(19) United States
(12) Patent Application Publication
(10) Pub. No.: US 2021/0335221 A1
(43) Pub. Date: Oct. 28, 2021

(54) DISPLAY PANEL AND DISPLAY DEVICE

(71) Applicant: Wuhan Tianma Micro-Electronics Co., Ltd., Wuhan (CN)

(72) Inventors: Yangzhao MA, Wuhan (CN); Meihong Wang, Wuhan (CN); Hao Dai, Wuhan (CN); Pengcheng Mou, Wuhan (CN); Lida Li, Wuhan (CN)

(73) Assignee: Wuhan Tianma Micro-Electronics Co., Ltd., Wuhan (CN)

(21) Appl. No.: 17/371,265

(22) Filed: Jul. 9, 2021

(30) Foreign Application Priority Data
Apr. 16, 2021 (CN) 202110414232.1

(51) Int. Cl. G09G 3/32

(52) U.S. Cl. CPC G09G 3/32; G09G 2310/0278

(57) ABSTRACT

Disclosed are a display panel and a display device. The display panel includes a display region including a first display region and an optical component region, multiple pixel driver circuits and a light-shielding layer. The optical component region includes multiple light-emitting elements and multiple light-transmitting regions. The multiple pixel driver circuits are electrically connected to the multiple light-emitting elements; the multiple pixel driver circuits are connected to one another through multiple pixel drive signal lines, and at least one of the multiple pixel drive signal lines is a transparent wire. The light-shielding layer is provided with a light-shielding pattern, and a vertical projection of a region on a light-emitting surface is located within a vertical projection of the light-shielding pattern on the light-emitting surface, where non-transparent structures in the multiple pixel driver circuits and the multiple pixel drive signal lines are located in the region.

### CROSS-REFERENCE TO RELATED APPLICATIONS

This application claims priority to Chinese patent application No. 202110414232.1 filed with CNIPA on Apr. 16, 2021, the disclosure of which is incorporated herein by reference in its entirety.

### TECHNICAL FIELD

Embodiments of the present disclosure relate to the field of display technologies and, in particular, a display panel and a display device.

### BACKGROUND

With the development of display technologies, because of the relatively large screen-to-body ratio and ultra-narrow bezels, full screens can greatly improve the visual effect for viewers compared with ordinary display screens, thus attracting extensive attention. At present, in the display device such as a mobile phone that uses the full screen, in order to achieve functions of taking selfies, making videophone calls and fingerprint identification, a front-facing camera, an earpiece, a fingerprint identification region, physical keys or the like are generally disposed on the front of the display device.

At present, in order to increase the screen-to-body ratio and avoid setting a hole-punching region which affects the complete display of an image, the camera and other optical components are generally disposed under the display panel, that is, the under-screen camera technology is adopted. Through setting the optical component region at the corresponding position of the display panel, not only the light-transmitting camera shooting can be performed, but also the image display can be achieved. However, the high display resolution and the high light transmittance of the current optical component region cannot be achieved at the same time. Setting a relatively high resolution is prone to reduce the light transmittance, thus affecting the quality of optical signals acquired by the camera.

### SUMMARY

The present disclosure provides a display panel and a display device so that a complete full-screen display is ensured, light transmission capability at a set position of an optical component is improved, and the quality of signals acquired by the optical component is improved.

In an embodiment, the present disclosure provides a display panel. The display panel includes a display region and multiple pixel driver circuits.

The display region includes a first display region and an optical component region.

The optical component region includes multiple light-emitting elements and multiple light-transmitting regions.

The multiple pixel driver circuits are electrically connected to the multiple light-emitting elements; the multiple pixel driver circuits are connected to one another through multiple pixel drive signal lines, and at least one of the multiple pixel drive signal lines is a transparent wire.

In an embodiment, the present disclosure further provides a display device including the above-mentioned display panel.

### BRIEF DESCRIPTION OF DRAWINGS

FIG. 1 is an enlarged partial view of an optical component region of a display panel according to an embodiment of the present disclosure;

FIG. 2 is a structural view of a display panel according to an embodiment of the present disclosure;

FIG. 3 is an enlarged partial view of the optical component region of the display panel shown in FIG. 2;

FIG. 4 is a structural view of a pixel driver circuit according to an embodiment of the present disclosure;

FIG. 5 to FIG. 7 are enlarged partial views of another three optical component regions of display panels according to an embodiment of the present disclosure;

FIG. 8 is an enlarged partial view of another optical component region of a display panel according to an embodiment of the present disclosure;

FIG. 9 is an enlarged partial view of another optical component region of a display panel according to an embodiment of the present disclosure;

FIG. 10 is an enlarged partial view of another optical component region of a display panel according to an embodiment of the present disclosure;

FIG. 11 is a structural view of a layout of a pixel driver circuit according to an embodiment of the present disclosure;

FIG. 12 is a structural view of a layout of another pixel driver circuit according to an embodiment of the present disclosure;

FIG. 13 is a structural view of a layout of another pixel driver circuit according to an embodiment of the present disclosure;

FIG. 14 is a structural view of a layout of another pixel driver circuit according to an embodiment of the present disclosure;

FIG. 15 is a structural view of a layout of another pixel driver circuit according to an embodiment of the present disclosure;

FIG. 16 is a partial sectional view of an optical component region of a display panel according to an embodiment of the present disclosure;

FIG. 17 is a structural view of a display device according to an embodiment of the present disclosure; and

FIG. 18 is a sectional structural view of a display device according to an embodiment of the present disclosure.

### DETAILED DESCRIPTION

The present disclosure is further described hereinafter in detail in conjunction with drawings and embodiments. It is to be understood that embodiments described hereinafter are intended to explain the present disclosure and not to limit the present disclosure. Additionally, it should be noted that for ease of description, only part, not all, of structures related to the present disclosure are illustrated in the drawings.

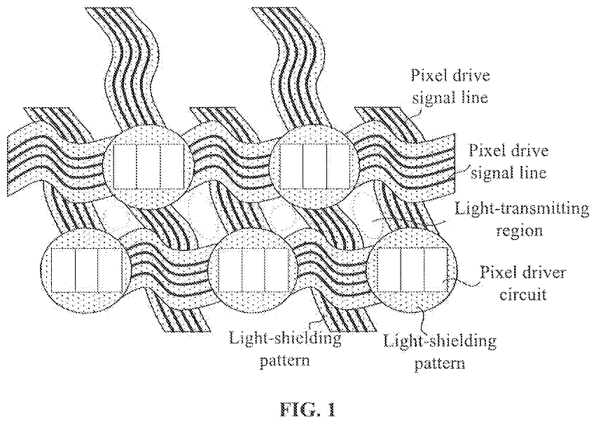

As described in the Background, FIG. 1 is an enlarged partial view of an optical component region of a display panel according to an embodiment of the present disclosure. Referring to FIG. 1, in the optical component region of the display panel, pixel driver circuits and pixel drive signal lines connected to the pixel driver circuits are all made of metal materials or other non-transparent materials, so that these regions substantially are non-transparent regions. In order to reduce light diffraction, a light-shielding pattern for light shielding is disposed at a position corresponding to a region where the pixel drive signal lines are located and a position corresponding to the pixel driver circuits. The inventor has found that even if a relatively small number of pixels are disposed in the optical component region, the light transmission performance of the optical component region is still relatively low, and if a relatively large number of pixels are disposed to increase the resolution of the region, the light transmission performance is greatly reduced.

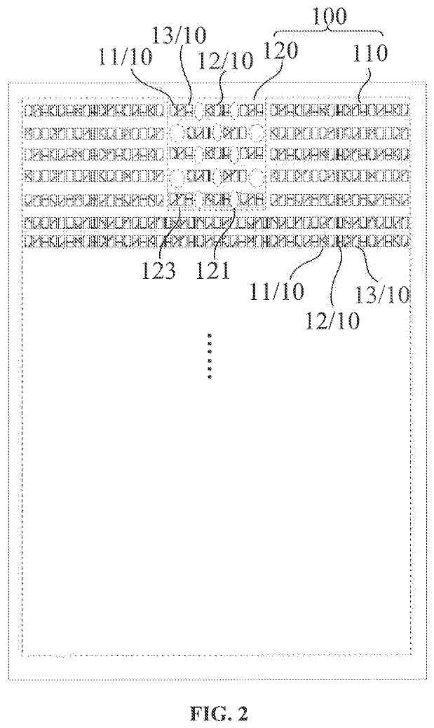

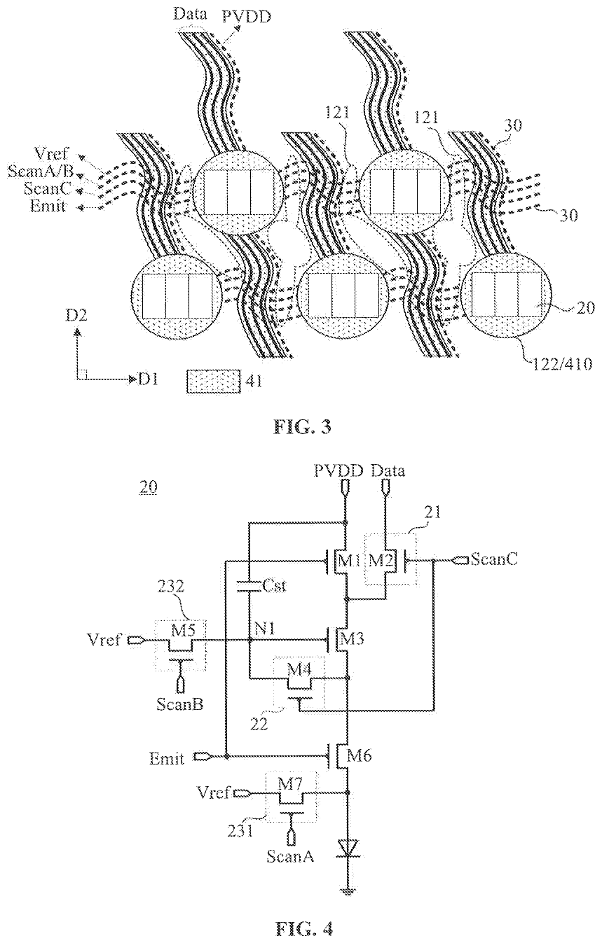

To further improve the light transmittance of the optical component region, an embodiment of the present disclosure further provides a display panel. FIG. 2 is a structural view of a display panel according to an embodiment of the present disclosure, and FIG. 3 is an enlarged partial view of the optical component region of the display panel shown in FIG. 2. Referring to FIG. 2 and FIG. 3, the display panel includes a display region 100, multiple pixel driver circuits 20 and a light-shielding layer. The display region 100 includes a first display region 110 and an optical component region 120. The optical component region 120 includes multiple light-emitting elements 10 and multiple light-transmitting regions 121. The multiple pixel driver circuits 20 are connected to the multiple light-emitting elements 10 (not shown in figures). It is to be noted that one pixel driver circuit 20 may be electrically connected to one light-emitting element 10, and one pixel driver circuit 20 may also be electrically connected to multiple light-emitting elements 10, which is not limited in the present disclosure. The multiple pixel driver circuits 20 are connected to one another through multiple pixel drive signal lines 30, and at least one of the multiple pixel drive signal lines 30 is a transparent wire (shown as the dotted line in figures). The light-shielding layer (not shown in figures) is provided with a light-shielding pattern 41, and a vertical projection of a region on a light-emitting surface is located within a vertical projection of the light-shielding pattern 41 on the light-emitting surface, where non-transparent structures in the multiple pixel driver circuits 20 and the multiple pixel drive signal lines 30 are located in the region.

The optical component region 120 is also located in the display region 100. Since the optical component region 120 is provided with the light-emitting elements 10, the optical component region 120 also has the display function. Different from the first display region 110, since an optical component needs to be set in the optical component region 120, a certain light transmittance of the optical component region 120 needs to be ensured, while the first display region 110 only for displaying does not need to transmit light. Therefore, the difference in pixel resolution exists between the optical component region 120 and the first display region 110. Compared to the first display region 110, the pixel density in the optical component region 120 is smaller, and the distance between at least part of pixels is relatively large, so as to form the light-transmitting regions 121.

The light-emitting elements 10 are driven and controlled to be turned on by the pixel driver circuits 20, and not only the light-emitting elements 10, but also the pixel driver circuits 20 are disposed in the optical component region 120. It is to be understood that the non-transparent structures exist in transistors and traces of the pixel driver circuits 20 and the pixel drive signal lines 30 connected to the pixel driver circuits 20, and the non-transparent structures block external light from being incident on the optical component disposed under the display panel, affecting the light transmission capability of the optical component region 120 and interfering with the signal acquisition of the optical component. The pixel drive signal lines 30, serving as signal transmission traces among the pixel driver circuits 20, shield part of regions among the pixel driver circuits 20, resulting in a decrease in the area of the light-transmitting regions 121, and even directly resulting in that the light-transmitting regions 121 cannot be connected. Based on this, in the embodiment, at least one pixel drive signal line 30 is set to a transparent wire, and at least part of signal lines in original non-transparent structures are configured in a transparent-wire manner, so that the number of non-transparent structures is reduced, the area of the light-transmitting regions 121 is increased, and the blocking of external light is reduced. The transparent wire may be made of a transparent conductive oxide material such as indium tin oxide (ITO), indium gallium zinc oxide (IGZO), and antimony-doped tin dioxide (ATO). Meanwhile, in the embodiments of the present disclosure, the vertical projection of the region on the light-emitting surface is located within a vertical projection of the light-shielding pattern 41 on the light-emitting surface, where the non-transparent structures in the pixel driver circuits 20 and the pixel drive signal lines 30 are located in the region, substantially, that is, the light-shielding pattern 41 is disposed in the region where the non-transparent structures in the pixel driver circuits 20 and the pixel drive signal lines 30 are located. In the embodiment of the present disclosure, the so-called region where the non-transparent structures are located does not strictly represent the projected region of the non-transparent structures, may also include the range of regions adjacent to the non-transparent structures. For example, a projected region of the pixel drive signal lines 30 and a gap region between two closely-spaced pixel drive signal lines 30 may be set to the region where the non-transparent structures are located. It is to be understood that the light-shielding pattern in the embodiments of the present disclosure is provided only in the region where the non-transparent structures in the pixel driver circuits 20 and the pixel drive signal lines 30 are located. In this way, the light shielding is achieved for the necessary region of the optical component region, and a relatively large light transmission area can be formed in the optical component region. At this time, the light-shielding pattern 41 can shield against the external light, the external light is prevented from being incident on the transistors in the pixel driver circuits 20, and thus the external light is prevented from affecting the working performance of the transistors. Moreover, the light-shielding pattern 41 is disposed in the region where the non-transparent structures in the pixel drive signal lines 30 are located, so that gaps between non-transparent traces, which are prone to produce diffraction, can be shielded, thus avoiding that the external light is diffracted by the gaps and then incident on the optical component, thereby affecting the quality of signals acquired by the optical component. In addition, the light-shielding pattern 41 is only disposed in the region where the non-transparent structures in the pixel driver circuits 20 and the pixel drive signal lines 30 are located, which represents that the vertical projection of the light-shielding pattern 41 on the light-emitting surface does not overlap the vertical projection of a region where pixel drive signal lines 30 made of the transparent wires are located on the light-emitting surface, and the light-shielding pattern 41 does not need to be disposed in the region where the pixel drive signal lines 30 made of the transparent wires are located. At this time, the area of the light-shielding pattern 41 can be reduced as much as possible, which is also conducive to reducing the shielding against the external light and improving the transmittance of the optical component region 120.

In addition, it should be noted that in the embodiments of the present disclosure, at least part of the pixel drive signal lines are set to transparent wires, gaps are formed between these transparent wires, or gaps are formed between the transparent wires and non-transparent wires. It is to be understood that even if a gap exists between two transparent wires, externally incident light cannot be significantly diffracted, that is, the diffraction phenomenon produced by the gap between two transparent wires is very slight; similarly, if a gap exists between a transparent wire and a non-transparent wire, externally incident light cannot be significantly diffracted, either, that is, the diffraction phenomenon produced by the gap between the transparent wire and the non-transparent wire is also very slight. Therefore, in the embodiments of the present disclosure, the diffraction phenomenon produced by the gap between signal lines can be improved by utilizing transparent pixel drive signal lines, and at this time, the light-shielding pattern in the gap region can be correspondingly removed so that the light transmittance of the region is achieved, and the area of the light-transmitting regions in the optical component region is increased.

In the embodiments of the present disclosure, the optical component region of the display panel is provided with multiple light-emitting elements and multiple light-transmitting regions, the multiple pixel driver circuits electrically connected to the multiple light-emitting elements are connected to one another through the multiple pixel drive signal lines, and at least one of the multiple pixel drive signal lines is a transparent wire; meanwhile, the display panel is provided with the light-shielding layer, and the vertical projection of the region on the light-emitting surface is located within the vertical projection of the light-shielding pattern on the light-emitting surface, where the non-transparent structures in the multiple pixel driver circuits and the multiple pixel drive signal lines are located in the region. Therefore, not only the non-transparent structures in the optical component region of the display panel are reduced, but also the light-shielding region is adaptively decreased. The embodiments of the present disclosure aim at insufficient light transmission capability of the region where the optical component of the existing display panel is located, to prevent the signal acquisition of the optical component from being affected. The normal working performance of the pixel driver circuits is ensured, at the same time, the display resolution requirement of the optical component region is satisfied, the light-shielding area is reduced as much as possible, the transmittance of the optical component region is improved, and the quality of optical signals acquired by the optical component is improved.

FIG. 4 is a structural view of a pixel driver circuit according to an embodiment of the present disclosure. Referring to FIG. 4, the pixel driver circuit includes seven transistors M1 to M7 and one capacitor Cst, that is, the pixel driver circuit is a 7T1C circuit. A first terminal of the first transistor M1 and a first electrode of the capacitor Cst are electrically connected to a power signal line PVDD; a control terminal of the first transistor M1 and a control terminal of the sixth transistor M6 are electrically connected to a light emission control signal line Emit; a first terminal of the second transistor M2 is electrically connected to a data signal line Data; a control terminal of the second transistor M2 is electrically connected to a scan signal line ScanC; a second terminal of the first transistor M1 and a second terminal of the second transistor M2 are electrically connected to a first terminal of the third transistor M3; a first terminal of the fifth transistor M5 and a first terminal of the seventh transistor M7 are both electrically connected to a reset signal line Vref; a control terminal of the fifth transistor M5 is electrically connected to a scan signal line ScanB; a control terminal of the seventh transistor M7 is electrically connected to a scan signal line ScanA; a second terminal of the fifth transistor M5, a second electrode of the capacitor Cst, a control terminal of the third transistor M3 and a second terminal of the fourth transistor M4 are electrically connected to a first node Ni; a second terminal of the third transistor M3 and a first terminal of the fourth transistor M4 are electrically connected to a first terminal of the sixth transistor M6; a control terminal of the fourth transistor M4 is electrically connected to the scan signal line ScanC; and a second terminal of the sixth transistor M6 and a second terminal of the seventh transistor M7 are electrically connected to an anode of the light-emitting element. Those skilled in the art may understand that the driving process of the 7T1C pixel driver circuit includes a reset stage, a data writing stage, and a light-emitting stage, which is not described in detail herein.

It can be seen that the multiple pixel drive signal lines connected to the pixel driver circuits include the power signal line PVDD, the light emission control signal line Emit, the data signal line Data, the scan signal line Scan, and the reset signal line Vref. The power signal line PVDD is used for providing the power signal for the light-emitting element of the pixel driver circuit to emit light; the light emission control signal line Emit is used for providing the light emission control signal for the first transistor M1 and the sixth transistor M6, to control the first transistor M1 and the sixth transistor M6 to be turned on; the reset signal line Vref is used for providing the reset signal for the first node Ni and the anode of the light-emitting element, to reset the potential of the first node Ni and the potential of the anode of the light-emitting element; the data signal line Data is used for providing the data signal which is stored in the capacitor Cst, so as to control the brightness of the light emitted by the light-emitting element in the light-emitting stage; the scan signal lines ScanA, ScanB and ScanC are used for controlling the corresponding transistors to be turned on, so as to switch to different working stages of the pixel driver circuit.

Based on the above arrangement of the pixel driver circuits and the pixel drive signal lines, in the embodiments of the present disclosure, at least one pixel drive signal line 30 of the power signal line PVDD, the light emission control signal line Emit, the data signal line Data, the scan signal line Scan, and the reset signal line Vref may be set to a transparent wire. Referring to FIG. 3, it can be seen that various types of pixel drive signal lines 30 between the interconnected pixel driver circuits occupy part of the space among the pixel driver circuits 20. It is to be understood that setting pixel drive signal lines 30 as transparent wires can increase the light transmission area of the region between the pixel driver circuits 20, and even enable the light-transmitting regions 121 to be connected to one another. At this time, the light transmission area of the entire optical component region 120 can be increased to some extent, and the light transmission performance of the region can be improved.

With continued reference to FIG. 3, in an embodiment of the present disclosure, the data signal line Data may be set to a non-transparent wire, and the power signal line PVDD, the light emission control signal line Emit, the scan signal line Scan, and the reset signal line Vref are all transparent wires; and the light-shielding pattern 41 is disposed in a region where the data signal line Data and the pixel driver circuits 20 are located.

It can be seen from FIG. 4, the data signal line Data is responsible for providing the data signal for the pixel driver circuits and controlling the brightness of the light emitted by the light-emitting elements. Based on this, in the embodiment of the present disclosure, the data signal line Data adopts the non-transparent wire, for example, the non-transparent wire is made of a metal material, so that the impedance on the data signal lines can be reduced, the influence of the voltage drop on the signal lines on data signals can be avoided, and thus the accuracy of the brightness of the light emitted by the light-emitting elements can be ensured.

It should be noted that in the embodiments of the present disclosure, any one or all of the pixel drive signal lines may be set to transparent or non-transparent wires, which may be selected and designed according to the direction of the trend or extension direction of the pixel drive signal lines. For example, one or more of the pixel drive signal lines extending in a row direction D1 may be selected to be set to transparent wires, and/or, one or more of the pixel drive signal lines extending in a column direction D2 may be selected to be set to transparent wires. The pixel drive signal lines in the embodiments of the present disclosure may be designed according to practical situations and requirements, and different embodiments are exemplified below.

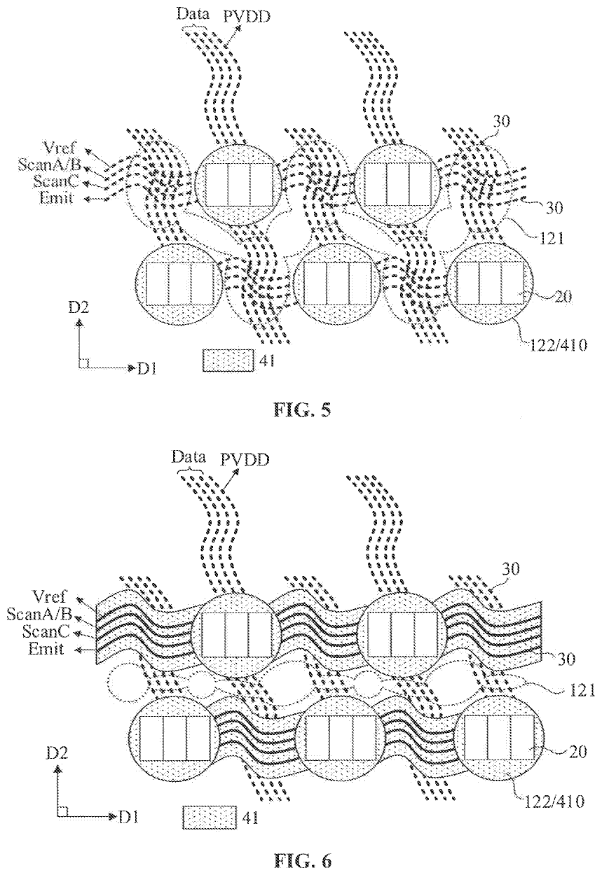

FIG. 5 to FIG. 7 show the enlarged partial views of another three optical component regions of display panels according to an embodiment of the present disclosure. Referring to FIG. 5, the power signal line PVDD, the light emission control signal line Emit, the data signal line Data, the scan signal line Scan (including the scan signal lines ScanA, ScanB, and ScanC), and the reset signal line Vref may all be set to transparent wires; the light-shielding pattern 41 is disposed in the region where the pixel driver circuits 20 are located. At this time, only the region where the pixel driver circuits 20 are located in the optical component region is provided with the light-shielding pattern 41, each pixel drive signal line 30 connected to the pixel drive circuits 20 has the transparent structure, the area of the light-transmitting regions 121 is further enlarged, so that the light transmittance of the optical component region is significantly increased, and the transmission of light signals is facilitated.

Alternatively, referring to FIG. 6, the power signal line PVDD and the data signal line Data may be set to transparent wires, while the light emission control signal line Emit, the scan signal line Scan, and the reset signal line Vref are set to non-transparent wires, and the light-shielding pattern 41 is disposed in a region where the pixel driver circuits 20, the light emission control signal line Emit, the scan signal line Scan, and the reset signal line Vref are located. At this time, pixel drive signal lines 30 extending along the direction D2, that is, along a longitudinal direction, in the optical component region are all transparent traces, so that connections of the light-transmitting regions between two adjacent rows of pixel driver circuits 20 can be realized, the area of the light-transmitting regions is significantly increased, and the light transmittance of the optical component is improved.

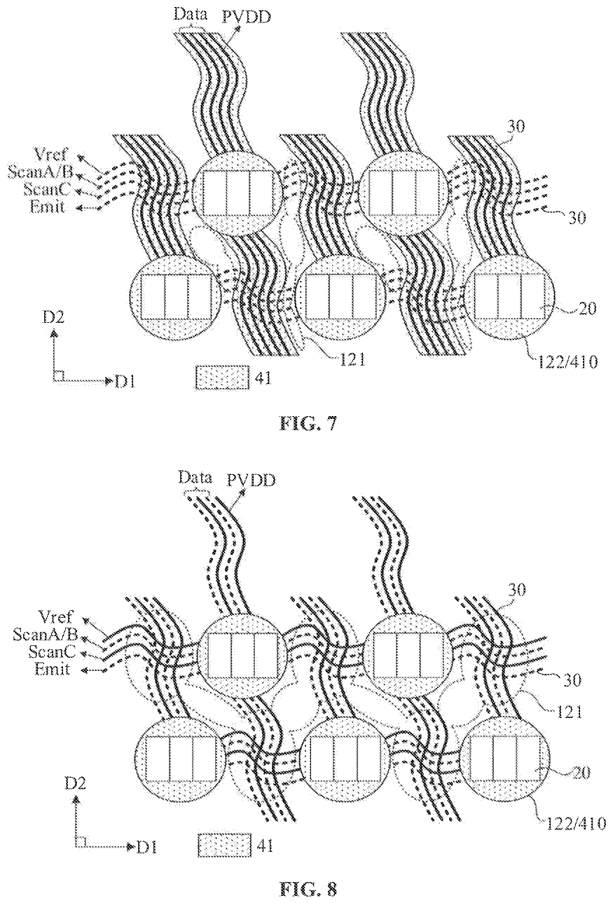

Alternatively, referring to FIG. 7, the light emission control signal line Emit, the scan signal line Scan, and the reset signal line Vref may be set to transparent wires, while the power signal line PVDD and the data signal line Data are non-transparent wires, and the light-shielding pattern 41 may be disposed in a region where the pixel driver circuits 20, the power signal line PVDD, and the data signal line Data are located. At this time, for the pixel driver circuits 20, the power signal line PVDD and the data signal line Data provide important signals for controlling the light emission of the light-emitting elements. Both the power signal line PVDD and the data signal line Data which are important for the pixel driving processes are made of a metal material having better conductivity so that the working quality of the pixel driver circuits can be ensured. Meanwhile, the light emission control signal line Emit, the scan signal line Scan, and the reset signal line Vref which extend in the direction D1, i.e., in a transverse direction, are set to transparent wires so that light-transmitting regions in the longitudinal direction can be connected, the area of the light-transmitting regions is significantly increased, and the light transmittance of the optical component is improved.

It should be noted that those skilled in the art may understand that as shown by the pixel driver circuit in FIG. 4, the first terminal of the seventh transistor M7 and the first terminal of the fifth transistor M5 are both used for receiving the reset signal Vref, to respectively control the reset of the potential of the first node Ni and the anode of the light-emitting element. The control terminal of the seventh transistor M7 and the control terminal of the fifth transistor M5 may be connected to the same scan signal, that is, the scan signal line ScanA and the scan signal line ScanB may be used as each other, and only one scan signal line is set. Thus, in order to simplify the drawings, the scan signal line ScanA and the scan signal line ScanB shown in above FIG. 3 and FIGS. 5 to 7 are reused as one scan signal line.

In sum, in the embodiments of the present disclosure, selecting transparent wires as the pixel drive signal lines in the optical component region needs to be considered based on striking a balance between the display effect and the acquisition effect of the optical component. On the basis of increasing the area of the light-transmitting regions, the working performance of the pixel driver circuits needs to be considered to ensure the transmission quality of signals in signal lines; meanwhile, the diffraction effect in gaps between signal lines needs to be considered to prevent the quality of acquired optical signals from being influenced by the diffraction.

Based on that gaps between non-transparent signal lines may produce the diffraction effect, the inventor has studied this in detail. In the embodiments of the present disclosure, on the basis that at least one pixel drive signal line may be a transparent signal line, and at least one pixel drive signal line may be set to a non-transparent wire. In other words, in the embodiments of the present disclosure, the pixel drive signal lines may be set in a hybrid manner of transparent wires and non-transparent wires. It is to be understood that the diffraction effect is produced based on gaps satisfying size requirements and having a regular arrangement, or based on gaps having the same refractive index and a regular arrangement. In the embodiments of the present disclosure, through the mixed use of transparent wires and non-transparent wires, the refractive index of gaps can be changed, and the regular arrangement of the pixel drive signal lines is disturbed. Therefore, the light transmission area can be increased, the diffraction effect can be avoided at the same time, and part of the light-shieling pattern used for shielding diffraction gaps can be removed.

FIG. 8 is an enlarged partial view of another optical component region of a display panel according to an embodiment of the present disclosure. Referring to FIG. 8, in the embodiment, among the multiple pixel drive signal lines 30 extending in parallel, at least one pixel drive signal line 30 between any two non-transparent pixel drive signal lines 30 may be set to a transparent wire. Exemplarily, transparent wires and non-transparent wires may be alternately arranged among four pixel drive signal lines 30 extending transversely and arranged in parallel. For example, the light emission control signal line Emit and the scan signal lines ScanA/B are transparent wires, the scan signal line ScanC and the reset signal line Vref are non-transparent wires. Meanwhile, transparent wires and non-transparent wires are alternately arranged among four pixel drive signal lines 30 extending longitudinally and arranged in parallel, as shown in FIG. 8.

At this time, gaps between non-transparent wires can be widened by alternately arranged transparent wires and non-transparent wires, and meanwhile, the refractive index of the gaps between the non-transparent wires is changed by the transparent wires. In other words, the alternately arranged transparent wires and non-transparent wires can be used for disordering the regular arrangement of the gaps, so that the gaps cannot completely satisfy the production condition of the diffraction effect. Therefore, the diffraction produced by the pixel drive signal lines is avoided to a certain extent, and the gaps which are prone to produce the diffraction do not need to be shielded by additionally disposing a light-shielding pattern.

It is to be understood that the alternative mixed arrangement manner of transparent and non-transparent wires shown in FIG. 8 is only one implementation of the present disclosure, and other mixed arrangements of non-transparent wires and transparent wires may be selected according to the actual influence of the gaps on the diffraction and the actual improved effect of the mixed arrangement on the diffraction. For example, two transparent wires are disposed between two non-transparent wires, the width or the refractive index of gaps between the non-transparent wires is increased; alternatively, it may be considered that non-transparent wires are disposed at edge positions of multiple pixel drive signal lines arranged in parallel, and pixel drive signal lines at middle positions all adopt transparent wires, and the like.

With continued reference to FIG. 3 and FIGS. 5 to 8, in the embodiments of the present disclosure, the multiple pixel driver circuits 20 may constitute multiple island-shaped regions 122 and form the multiple light-transmitting regions 121 located among the multiple island-shaped regions 122, and the multiple island-shaped regions 122 are sequentially arranged in the row direction D1 and the column direction D2. Each island-shaped region 122 includes at least two adjacent pixel driver circuits 20, and the multiple island-shaped regions 122 are connected to one another through the multiple pixel drive signal lines 30.

In the embodiment, each pixel driver circuit is in one-to-one correspondence with one light-emitting element (in other embodiments, each pixel driver circuit may be connected to two or more light-emitting elements correspondingly). For the display panel, it is generally ensured that each pixel includes light-emitting elements of three colors, i.e., red, green and blue. In the embodiments of the present disclosure, it may be set that the multiple light-emitting elements include a red light-emitting element, a green light-emitting element, and a blue light-emitting element, the multiple light-emitting elements constitute multiple pixels, and the multiple pixels are disposed in one-to-one correspondence with the multiple island-shaped regions. Each pixel includes one red light-emitting element, one green light-emitting element, and one blue light-emitting element which are adjacent to one another.

Referring to FIG. 2 and FIG. 3, exemplarily, each pixel 123 includes one red light-emitting element 11, one green light-emitting element 12, and one blue light-emitting element 13 which are adjacent to one another, these three light-emitting elements are sequentially arranged in the color order of red, green and blue, and the corresponding three pixel driver circuits 20 are also adjacent to one another and constitute one island-shaped region 122.

With continued reference to FIG. 3 and FIGS. 5 to 8, in the optical component region 120, it may be set that pixel driver circuits 20 corresponding to multiple light-emitting elements in each pixel are adjacently disposed and constitute one island-shaped region 122. At least two pixel driver circuits 20 are adjacently disposed to constitute one island-shaped region 122, so that the non-transparent structures in the optical component region 120 may be concentrated, which is conducive to enlarging the area of the light-transmitting regions 121. In addition, the concentrated pixel driver circuits 20 may adopt a concentrated light-shielding pattern to shield against light so that the difficulty in manufacturing the light-shielding pattern is reduced, and the manufacture of the light-shielding pattern is facilitated.

Further, it may be set that the light-shielding pattern includes a circular light-shielding portion 410, and the vertical projection of the multiple pixel driver circuits 20 on the light-emitting surface is located within a vertical projection of the circular light-shielding portion 410 on the light-emitting surface. In other words, the pixel driver circuits 20 may be disposed in a region where the circular light-shielding portion 410 is located, and the pixel driver circuits 20 are shielded by the circular light-shielding portion 410. As shown in FIG. 3 and FIGS. 5 to 8, each island-shaped region 122 is correspondingly provided with one circular light-shielding portion 410, and pixel driver circuits 20 in each island-shaped region 122 are all shielded by the same circular light-shielding portion 410. It should be noted that in view of the light transmission and diffraction effect, the inventor found that adopting the circular light-shielding portion 410 has greater light transmittance than adopting light-shielding portions of other shapes. Moreover, light is prevented from being significantly diffracted at the edge of the light-shielding portion, thereby facilitating the external light acquisition of the optical component.

Further, for pixel drive signal lines 30 connected to pixel driver circuits 20 in the same island-shaped region 122, it may be set that a vertical projection of gaps between adjacent and non-transparent pixel drive signal lines 30 on the light-emitting surface is located in the vertical projection of the light-shielding pattern 41 on the light-emitting surface. In other words, in the embodiments of the present disclosure, part of the light-shielding structure in the light-shielding pattern 41 may be disposed in the region where the gaps between non-transparent pixel drive signal lines 30 are located to shield the gaps between non-transparent pixel drive signal lines 30, to avoid the significant diffraction phenomenon produced by the gaps comparably sized to the wavelength of external light. In detail, in the embodiments of the present disclosure, part of the light-shielding structure of the light-shielding pattern 41 needs to be disposed in the region of the vertical projection of the gaps between non-transparent pixel drive signal lines 30, and part of the light-shielding structure needs to be disposed in the region of the vertical projection where the pixel driver circuits are located. As in the region where transparent pixel drive signal lines 30 are located, and even the region where the non-transparent pixel drive signal lines 30 are located, the light-shielding structure may not be set.

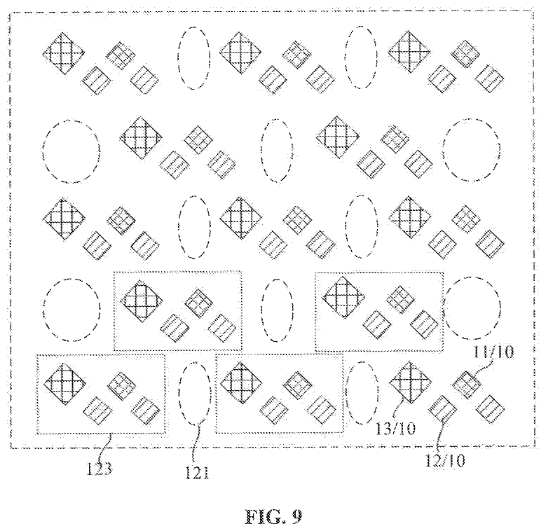

It should be noted that as in the above embodiments, the number and color proportion of the light-emitting elements in the pixels is only one exemplary embodiment of the present disclosure. In other embodiments, it may be set that each pixel includes one red light-emitting element, two green light-emitting elements, and one blue light-emitting element which are adjacent to one another. FIG. 9 is an enlarged partial view of another optical component region of a display panel according to an embodiment of the present disclosure. Referring to FIG. 9, each pixel includes one red light-emitting element 11, two green light-emitting elements 12, and one blue light-emitting element 13 which are adjacent to one another. The light-emitting efficiency of the green light-emitting element 12 is relatively low, and two green light-emitting elements 12 of relatively small areas are disposed, so that the low brightness of green light and the like can be avoided, and the color scheme effect of three primary colors of red, green and blue can be improved. It is to be understood that the arrangement and shape of the four light-emitting elements of red, green and blue colors as shown in the figure is also an example of the present disclosure, which may be designed by those skilled in the art according to practical requirements and may not be limited herein.

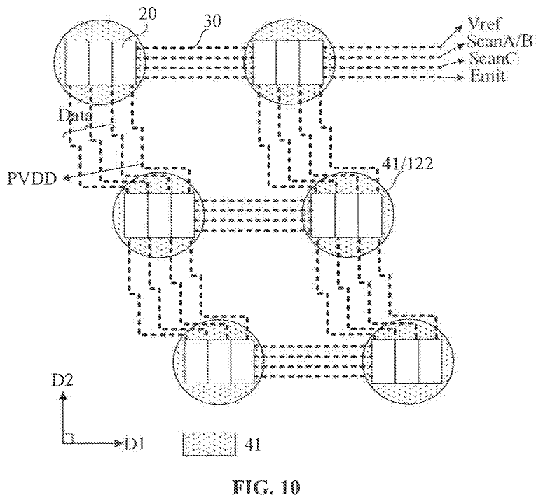

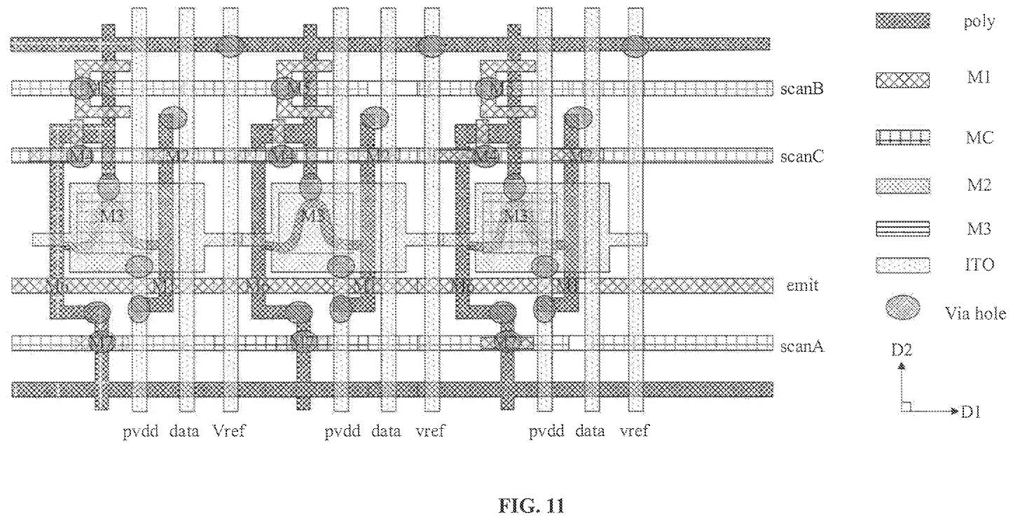

In addition, as for the setting scheme of island-shaped regions in the optical component region, the embodiments of the present disclosure also provide an exemplary implementation. With continued reference to FIG. 3 and FIGS. 5 to 8, island-shaped regions 122 of the multiple island-shaped regions 122 in two adjacent rows are staggered from each other. At this time, it may further be set that island-shaped regions 122 of the multiple island-shaped regions 122 in any row are connected to island-shaped regions 122 of the multiple island-shaped regions 122 in an interlaced row through the multiple pixel drive signal lines 30. FIG. 10 is an enlarged partial view of another optical component region of a display panel according to an embodiment of the present disclosure. Referring to FIG. 10, in another embodiment of the present disclosure, it may be set that island-shaped regions 122 in any row are connected to island-shaped regions 122 in an adjacent row in one-to-one correspondence through the multiple pixel drive signal lines 30. In order to ensure the maximum area of the light-transmitting regions and improve the transmittance of the optical component region, it may be set that pixel drive signal lines 30 connected to two pixel driver circuits are arc-shaped or broken-line shaped. It is to be understood that the shape and size of the gaps between signal lines can be adjusted by appropriately adjusting the extension direction of the pixel drive signal lines 30 to disturb the regular arrangement of the gaps between the signal lines, so that the gaps cannot fully satisfy the generation condition of diffraction, and the diffraction of external incident light can be reduced to some extent.

The above embodiments all discuss the transparency of the pixel drive signal lines and the corresponding light-shielding pattern, it is considered that the pixel driver circuits occupy a relatively large area of the optical component region, the embodiments of the present disclosure further study the non-transparent structures in the pixel driver circuits and the corresponding light-shielding pattern.

FIG. 11 is a structural view of a layout of a pixel driver circuit according to an embodiment of the present disclosure. With continued reference to FIG. 4 and FIG. 11, the pixel driver circuit includes multiple transistors and connecting lines connected to the multiple transistors. The 7T1C pixel driver circuit shown in FIG. 4 is taken as an example. The 7T1C pixel driver circuit includes multiple transistors and connecting lines connected to corresponding transistors, the connecting lines include a power connecting line pvdd, a light emission control connecting line emit, a data connecting line data, a scan connecting line scan, and a reset connecting line vref. Based on this, it may be set in the embodiments of the present disclosure that at least one of the power connecting line pvdd, the light emission control connecting line emit, the data connecting line data, the scan connecting line scan, and the reset connecting line vref is a transparent wire. In the present embodiment, the power connecting line pvdd, the data connecting line data, and the reset connecting line vref are made of ITO. A vertical projection of a region on the light-emitting surface is located within the vertical projection of the light-shielding pattern (not shown in the figure) on the light-emitting surface, where the non-transparent structures in the multiple transistors and the connecting lines are located in the region. At this time, part of wires in the pixel driver circuits are transparent wires so that the quantity or area of non-transparent structures in the pixel driver circuits is reduced. In addition, in the present embodiment, the light-shielding pattern is further disposed in the region where the non-transparent structures in the transistors and the connecting lines are located, so that the transistors are protected and gaps between the connecting lines are prevented from producing diffraction. Moreover, the area of the light-shielding pattern can be further reduced, and the light transmission area can be increased for the entire optical component region, being conducive to improving the transmittance.

It is to be understood that extension directions of the connecting lines in the pixel driver circuits are different. In the present embodiment, the power connecting line, the light emission control connecting line, the data connecting line, the scan connecting line, and the reset connecting line whose vertical projections on the light-emitting surface do not intersect may be transparent wires. At this time, different connecting lines set to transparent wires may be formed in the same film layer. On one hand, disposing multiple connecting lines in the same layer can reduce the number of film layers in the array substrate and the thickness of the array substrate, and it also is conducive to reducing the manufacture process of the array substrate; on the other hand, the step of performing insulation during manufacture of intersected connecting lines can be avoided, processes can also be reduced, and the cost is saved.

It can be seen from FIG. 11 that among the power connecting line pvdd, the light emission control connecting line emit, the data connecting line data, the scan connecting line scan, and the reset connecting line vref, the power connecting line pvdd and the data connecting line data extend in the column direction D2, the light emission control connecting line emit and the scan connecting lines scanA, scanB, and scanC extend transversely, and the reset connecting line vref may be set to extend transversely or may be set to extend in the column direction D2. Based on this, in the embodiments of the present disclosure, connecting lines extending in the same direction may be set to transparent wires. Exemplarily, as shown in FIG. 11, the power connecting line pvdd, the data connecting line data, and the reset connecting line vref may be set to transparent wires, and the light emission control connecting line emit and the scan connecting line scanA, scanB and scanC may be set to non-transparent wires; part of the light-shielding pattern is disposed in a region where the transistors, the light emission control connecting line emit, and the scan connecting lines scanA, scanB and scanC are located. The reset connecting line vref is disposed to extend in the column direction D2. It is to be understood that those skilled in the art may also choose to set the reset connecting line Vref to extend in the row direction D1 and set the light emission control connecting line emit, the scan connecting lines scanA, scanB, scanC, and the reset connecting line Vref extending in the row direction D1 to transparent wires, which is not illustrated by figures herein.

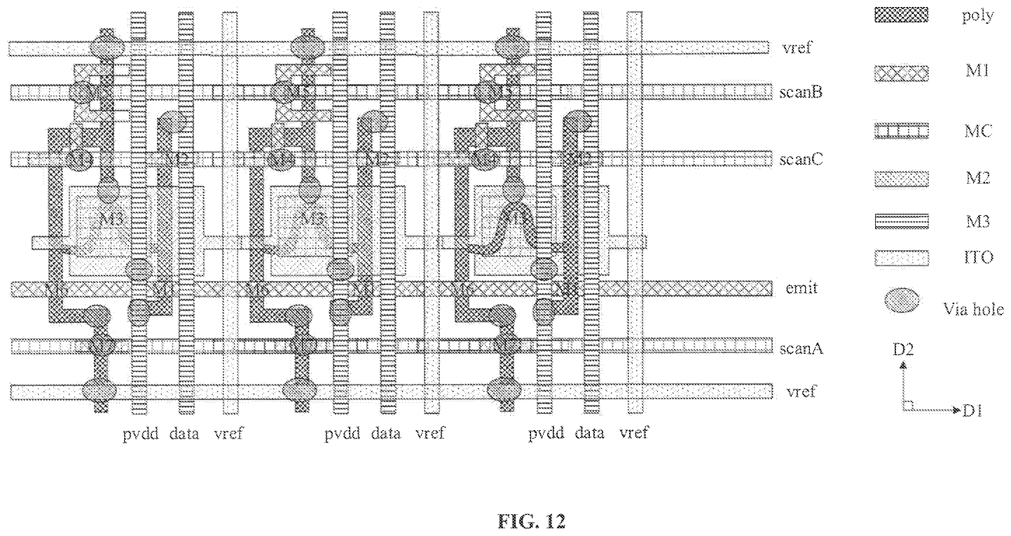

FIG. 12 is a structural view of a layout of another pixel driver circuit according to an embodiment of the present disclosure. Referring to FIG. 12 and FIG. 4, in another embodiment of the present disclosure, the reset connecting line Vref may be a transparent wire, the power connecting line pvdd, the data connecting line data, the light emission control connecting line emit, and the scan connecting lines scanA, scanB and scanC are non-transparent wires; part of the light-shielding pattern (not shown in the figure) is disposed in a region where the transistors, the power connecting line pvdd, the data connecting line data, the light emission control connecting line emit, and the scan connecting lines scanA, scanB and scanC are located.

In the present embodiment, the reset connecting line vref may be set to a mesh-shaped structure, that is, the pixel driver circuit includes reset connecting lines vref extending in the row direction D1 and reset connecting lines vref extending in the column direction D2 which are electrically connected. The impedance on the connecting lines is reduced by the mesh-shaped reset connecting lines vref, the influence of the voltage drop on the reset connecting lines vref on the reset signals is avoided, and thus the reset voltage of the first node in the pixel driver circuit is ensured to be accurate. It is to be understood that the potential of the first node determines the writing of data signals, that is, the brightness of the light emitted by the light-emitting element to some extent. By the mesh-shaped reset connecting lines vref, each pixel driver circuit is ensured to be uniformly reset so that the display uniformity is better. In addition, the mesh-shaped reset connecting lines vref occupy more area, so that setting the mesh-shaped reset connecting lines vref to the transparent wires is conducive to increasing the light transmittance of the region where the pixel driver circuits in the optical component region are located.

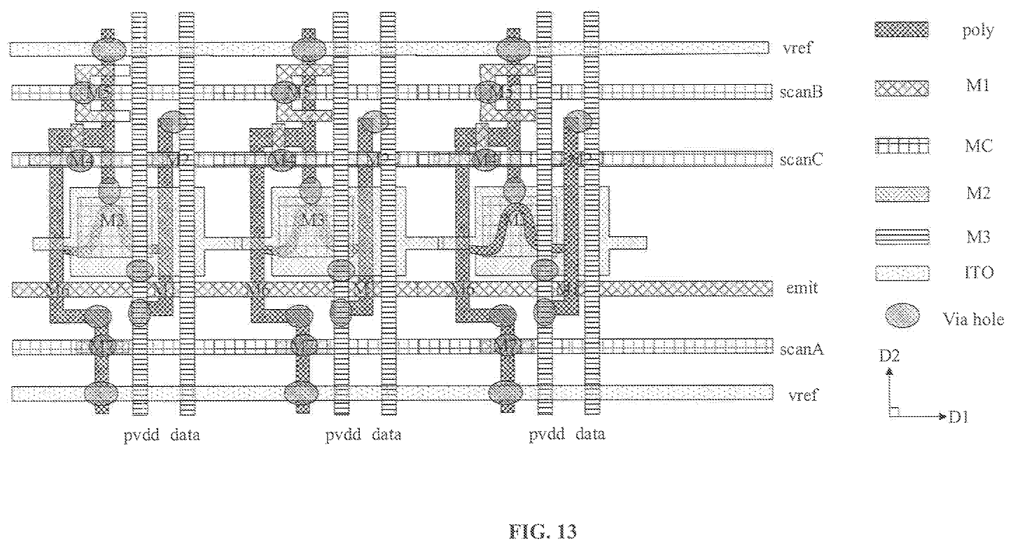

FIG. 13 is a structural view of a layout of another pixel driver circuit according to an embodiment of the present disclosure. Comparing FIG. 12 and FIG. 13, in the embodiments of the present disclosure, on the basis of the reset connecting line vref being the transparent wire, the reset connecting line vref may be set to extend only in the row direction D1.

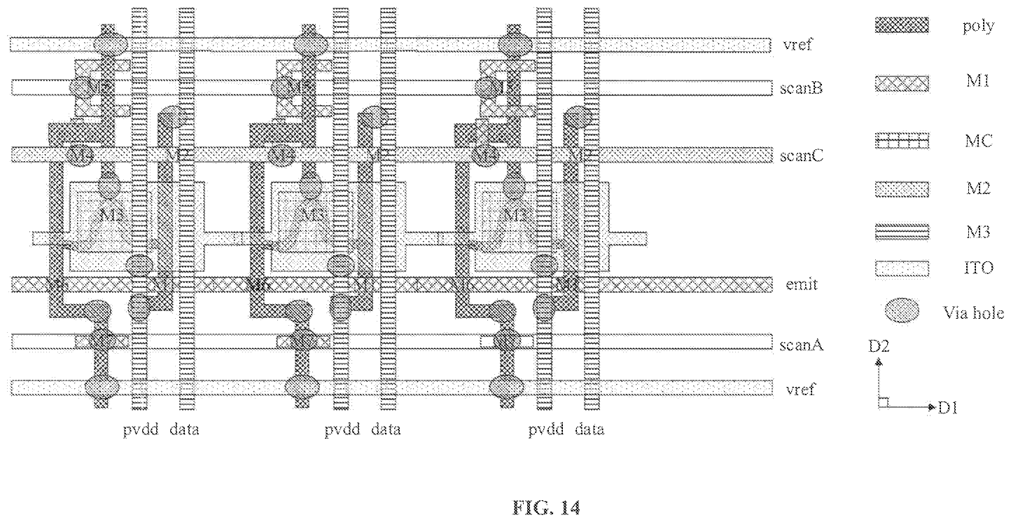

FIG. 14 is a structural view of a layout of another pixel driver circuit according to an embodiment of the present disclosure. Referring to FIG. 4 and FIG. 14, a vertical projection of the reset connecting line vref on the light-emitting surface does not intersect a vertical projection of the scan connecting lines scanA, scanB and scanC on the light-emitting surface; and the reset connecting line vref and at least part of the scan connecting lines are transparent wires. The power connecting line pvdd, the data connecting line data, and the light emission control connecting line emit are non-transparent wires. The light-shielding pattern (not shown in the figure) is disposed in a region where the transistors, the power connecting line pvdd, the data connecting line data and the light emission control connecting line emit are located.

With continued reference to FIG. 4 and FIG. 14, the pixel driver circuit 20 includes a data write module 21, a data compensation module 22, a first reset module 231, and a second reset module 232; and the scan connecting line includes a first scan connecting line scanA, a second scan connecting line scanB, and a third scan connecting line scanC. The first scan connecting line scanA is electrically connected to a control terminal of the first reset module 231, the second scan connecting line scanB is electrically connected to a control terminal of the second reset module 232, and the third scan connecting line scanC is electrically connected to a control terminal of the data write module 21 and a control terminal of the data compensation module 22, separately. The first scan connecting line scanA and the second scan connecting line scanB may be set to transparent wires, and the third scan connecting line scanC is a non-transparent wire.

In the present embodiment, the reset connecting line vref is disposed to extend in the row direction D1 and is set to a transparent wire. Meanwhile, the first scan connecting line scanA and the second scan connecting line scanB which also extend in the row direction D1 are also set to transparent wires. At this time, this kind pixel driver circuit can reduce the area of the non-light-transmitting structure. In addition, in the pixel driver circuit, the first scan connecting line scanA and the second scan connecting line scanB are responsible for providing signals for the reset module, the gate voltage drop of the first scan connecting line scanA and the second scan connecting line scanB has a relatively small influence on the reset of the potential of the first node and has a relatively small influence on the display uniformity. The third scan connecting line scanC is responsible for writing data signals, directly influences the accuracy of data writing, directly influences the threshold compensation of the drive transistor M3, and greatly influences the display. The third scan connecting line scanC is set to a non-transparent wire made of a metal material so that the voltage drop on the signal line can be reduced, and accurate writing of data signals is ensured.

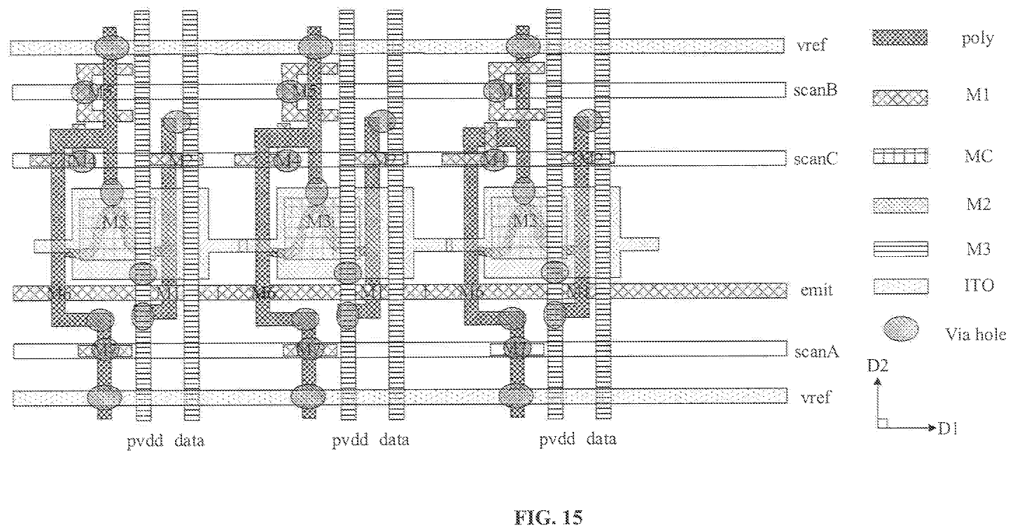

FIG. 15 is a structural view of a layout of another pixel driver circuit according to an embodiment of the present disclosure. Comparing FIG. 14 and FIG. 15, in another embodiment of the present disclosure, the third scan connecting line scanC extending in the row direction D1, the first scan connecting line scanA, and the second scan connecting line scanB are all manufactured and formed to transparent wires. With continued reference to FIGS. 12 to 15, the display panel in the embodiments of the present disclosure includes a base substrate, a polysilicon layer poly, a first metal layer M1, a capacitor metal layer MC, a second metal layer M2, a third metal layer M3, a transparent conductive layer (taking ITO as an example), and an anode layer (not shown in the figures) which are sequentially stacked on the base substrate. That is, as indicated by marks in figures, the polysilicon layer poly, the first metal layer M1, the capacitor metal layer MC, the second metal layer M2, the third metal layer M3, and the transparent conductive layer ITO are sequentially stacked on the base substrate from bottom to top. It is to be understood that in order to achieve the insulation between different film layers, interlayer insulating layers are further disposed between the above film layers, which is not excessively limited herein.

As shown in the embodiment of FIG. 11, it may be set that the light emission control signal line Emit (not shown in the figure) and the light emission control connecting line emit are disposed in the first metal layer M1, the scan signal line ScanC (not shown in the figure) and the scan connecting line scan are disposed in the second metal layer M2, the light-shielding pattern (not shown in the figure) may be disposed in the third metal layer M3, and the power signal line PVDD (not shown in the figure), the data signal line Data (not shown in the figure), the reset signal line Vref (not shown in the figure), the power connecting line pvdd, the data connecting line data, and the reset connecting line vref are disposed in the transparent conductive layer ITO.

It should be noted that in the structure of the layouts of the pixel driver circuits shown in FIGS. 11 to 15, different film layers need to be connected, which is illustrated through via holes in the embodiments of the present disclosure. Those skilled in the art may understand that an interlayer insulating layer may be disposed between two film layers stacked on top of each other for insulation, and after the interlayer insulating layer is formed, a via hole may be formed at a set position through the etching process so as to expose part of connecting lines in a conductive film layer under the interlayer insulating layer. At this time, the conductive film layer is formed on the surface of the interlayer insulating layer, and part of the conductive structure is filled in the via hole, so that the electrical connection between the connecting lines in the upper film layer and the lower film layer can be achieved.

It is to be understood that if the power signal line PVDD, the data signal line Data, the reset signal line Vref, the power connecting line pvdd, the data connecting line data, and the reset connecting line vref are all transparent wires, which are disposed in the transparent conductive layer ITO, the third metal layer M3 in the array substrate can be saved for manufacturing the light-shielding pattern, that is, the third metal layer M3 is the light-shielding layer. Based on this, the array substrate does not need to be additionally provided with a light-shieling layer for forming the light-shieling pattern, which is conducive to reducing the thickness of the array substrate and also the manufacture process of the array substrate, and saving the cost.

With continued reference to FIG. 12 and FIG. 15, similarly, the display panel in the embodiments includes a base substrate (not shown in the figure), a polysilicon layer poly, a first metal layer M1, a capacitor metal layer MC, a second metal layer M2, a third metal layer M3, a transparent conductive layer (taking ITO as an example), and an anode layer (not shown in the figure) which are sequentially stacked on the base substrate. In these embodiments, the light-shielding pattern may be disposed between the third metal layer M3 and the anode layer.

Of course, in addition to the positions for disposing the light-shielding pattern provided in the above embodiments, in the embodiments of the present disclosure, the light-shielding pattern may be disposed between the base substrate and the polysilicon layer. In other words, the light-shielding pattern may be pre-formed on the base substrate before the pixel driver circuits are manufactured on the base substrate.

FIG. 16 is a partial sectional view of an optical component region of a display panel according to an embodiment of the present disclosure. Referring to FIG. 16, in the present embodiment of the present disclosure, a vertical projection of the multiple light-emitting elements 10 on the light-emitting surface at least partially overlaps the vertical projection of the multiple pixel driver circuits 20 on the light-emitting surface, and the multiple pixel driver circuits 20 are located on one side of the multiple light-emitting elements 10 facing away from the light-emitting surface. In other words, those skilled in the art may understand that in the embodiments of the present disclosure, the pixel driver circuits 20 corresponding to the light-emitting elements 10 may be disposed under the light-emitting elements 10 in the optical component region 120, that is, in such a manner that the pixel driver circuits 20 are built-in.

It should be noted that considering the fact that the pixel driver circuits 20 partially overlap the above light-emitting elements 10, and anodes or cathodes in the light-emitting elements 10 are generally made of a non-transparent metal electrode, therefore, when the pixel drive signal lines connected to the pixel driver circuits 20 and the connecting lines in the pixel driver circuits 20 are disposed, it may be considered that pixel drive signal lines and connecting lines in the projection overlapping region are set to non-transparent wires. For example, these pixel drive signal lines and connecting lines may be made of a metal material, so that the conductivity of the pixel drive signal lines and the connecting lines in this part can be ensured at this time, and influence on signal transmission due to the overlarge voltage drop generated by the impedance on the wires can be avoided.

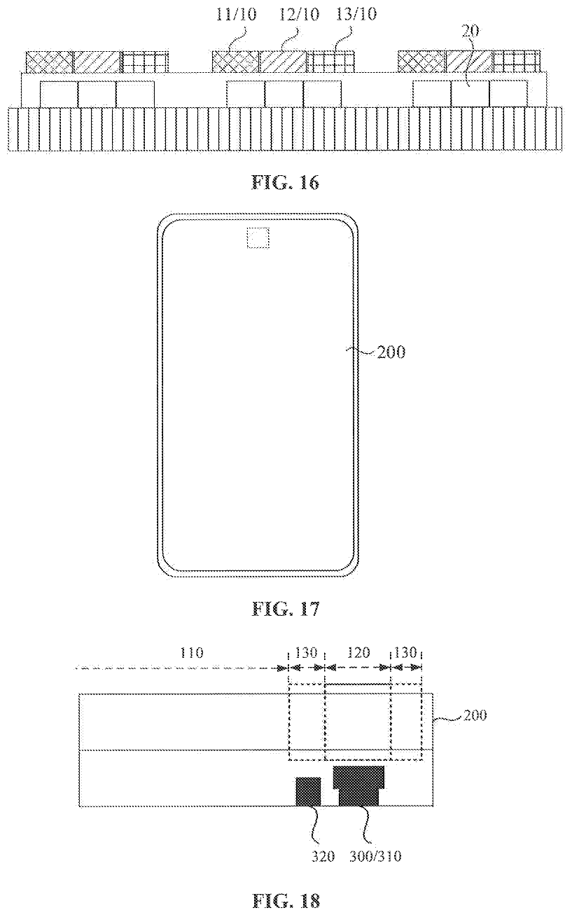

Based on the same inventive concept, the embodiments of the present disclosure further provide a display device including the display panel of any one of the embodiments of the present disclosure. FIG. 17 is a structural view of a display device according to an embodiment of the present disclosure. Referring to FIG. 17, the display device includes the display panel 200 of the above embodiments, therefore, the display device provided by the embodiments of the present disclosure also has the beneficial effects described in the above embodiments and is not repeated herein. Exemplarily, the display device may be a mobile phone, a computer, a smart wearable device (for example, a smart watch), an onboard display device, and other electronic devices, which is not limited in the embodiments of the present disclosure.

FIG. 18 is a sectional structural view of a display device according to an embodiment of the present disclosure. Referring to FIG. 18, the display device further includes an optical component 300, and the optical component 300 is disposed to correspond to the optical component region 120. The optical component 300 includes, for example, a camera 310, and the camera 310 is disposed to correspond to the optical component region 120.

With continued reference to FIG. 18, in the display device, the display region of the display panel may further be set to include a second display region 130, and the second display region 130 is disposed between the first display region 110 and the optical component region 120. The second display region 130 is substantially a transition region between the first display region 110 and the optical component region 120, the pixel resolution of the second display region 130 may be set to equal to one of the pixel resolution of the first display region 110 or the pixel resolution of the optical component region 120; alternatively, the pixel resolution of the second display region 130 may be set to between the pixel resolution of the first display region 110 and the pixel resolution of the optical component region 120. Moreover, the pixel resolution of the second display region 130 may be set to adopt a gradual design, that is, in this transition region, the pixel resolution is gradually changed from the pixel resolution of the first display region 110 to the pixel resolution of the optical component region 120. If the display region further includes the second display region 130 and the display panel is provided with a sensor in addition to the camera, the camera 310 may be disposed to correspond to the position of the optical component region 120, and the sensor 320 may be disposed to correspond to the position of the optical component region 120; alternatively, the sensor 320 may be disposed to correspond to the position of the second display region 130.

It is to be noted that the preceding are only exemplary embodiments of the present disclosure and the principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure has been described in detail via the preceding embodiments, the present disclosure is not limited to the preceding embodiments and may include more equivalent embodiments without departing from the inventive concept of the present disclosure. The scope of the present disclosure is determined by the scope of the appended claims.

What is claimed is:

1. A display panel, comprising:
a display region, comprising a first display region and an optical component region;
wherein the optical component region comprises a plurality of light-emitting elements and a plurality of light-transmitting regions; and
a plurality of pixel driver circuits, wherein the plurality of pixel driver circuits are electrically connected to the plurality of light-emitting elements; the plurality of pixel driver circuits are connected to one another through a plurality of pixel drive signal lines, and at least one of the plurality of pixel drive signal lines is a transparent wire.

2. The display panel according to claim 1, wherein at least one of the plurality of pixel drive signal lines is a non-transparent wire.

3. The display panel according to claim 1, further comprising a light-shielding layer, wherein the light-shielding layer is provided with a light-shielding pattern, and a vertical projection of a region on a light-emitting surface is located within a vertical projection of the light-shielding pattern on the light-emitting surface, wherein non-transparent structures in the plurality of pixel driver circuits and the plurality of pixel drive signal lines are located in the region.

4. The display panel according to claim 3, wherein the plurality of pixel drive signal lines comprise a power signal line, a light emission control signal line, a data signal line, a scan signal line, and a reset signal line, and at least one of the power signal line, the light emission control signal line, the data signal line, the scan signal line, or the reset signal line is a transparent wire.

5. The display panel according to claim 4, wherein the data signal line is a non-transparent wire, and the power signal line, the light emission control signal line, the scan signal line, and the reset signal line are all transparent wires; and
the light-shielding pattern is disposed in a region where the data signal line and the plurality of pixel driver circuits are located.

6. The display panel according to claim 4, wherein the power signal line, the light emission control signal line, the data signal line, the scan signal line, and the reset signal line are all transparent wires; and
the light-shielding pattern is disposed in a region where the plurality of pixel driver circuits are located.

7. The display panel according to claim 3, wherein the light-shielding pattern comprises a circular light-shielding portion, and a vertical projection of the plurality of pixel driver circuits on the light-emitting surface is located within a vertical projection of the circular light-shielding portion on the light-emitting surface.

8. The display panel according to claim 2, wherein at least one pixel drive signal line between any two non-transparent pixel drive signal lines among the plurality of pixel drive signal lines extending in parallel is a transparent wire.

9. The display panel according to claim 4, wherein one of the plurality of pixel driver circuits comprises a plurality of transistors and a plurality of connecting lines connected to the plurality of transistors, the plurality of connecting lines comprise a power connecting line, a light emission control connecting line, a data connecting line, a scan connecting line, and a reset connecting line; and at least one of the power connecting line, the light emission control connecting line, the data connecting line, the scan connecting line, or the reset connecting line is a transparent wire; and
a vertical projection of a region on the light-emitting surface is located within the vertical projection of the light-shielding pattern on the light-emitting surface, wherein non-transparent structures in the plurality of transistors and the plurality of connecting lines are located in the region.

10. The display panel according to claim 9, wherein the power connecting line, the light emission control connecting line, the data connecting line, the scan connecting line, and the reset connecting line whose vertical projections on the light-emitting surface do not intersect are transparent wires.

11. The display panel according to claim 9, wherein a vertical projection of the reset connecting line on the light-emitting surface does not intersect a vertical projection of the power connecting line on the light-emitting surface and a vertical projection of the data connecting line on the light-emitting surface, respectively; the power connecting line, the data connecting line, and the reset connecting line are transparent wires, and the light emission control connecting line and the scan connecting line are non-transparent wires; and part of the light-shielding pattern is disposed in a region where the plurality of transistors, the light-emitting control connecting line and the scan connecting line are located; or
the reset connecting line is a transparent line, and the power connecting line, the data connecting line, the light emission control connecting line, and the scan connecting line are non-transparent wires; and part of the light-shielding pattern is disposed in a region where the plurality of transistors, the power connecting line, the data connecting line, the light emission control connecting line, and the scan connecting line are located.

12. The display panel according to claim 9, wherein a vertical projection of the reset connecting line on the light-emitting surface and a vertical projection of the scan connecting line on the light-emitting surface do not intersect with each other; the reset connecting line and at least part of the scan connecting line are transparent wires, and the power connecting line, the data connecting line, and the light emission control connecting line are non-transparent wires; and
the light-shielding pattern is disposed in a region where the plurality of transistors, the power connecting line, the data connecting line, and the light emission control connecting line are located.

13. The display panel according to claim 12, wherein one of the plurality of pixel driver circuits comprises a data write module, a data compensation module, a first reset module, and a second reset module; and the scan connecting line comprises a first scan connecting line, a second scan connecting line, and a third scan connecting line;
the first scan connecting line is electrically connected to a control terminal of the first reset module, the second scan connecting line is electrically connected to a control terminal of the second reset module, and the third scan connecting line is electrically connected to a control terminal of the data write module and a control terminal of the data compensation module separately; and
the first scan connecting line and the second scan connecting line are transparent wires, and the third scan connecting line is a non-transparent wire.

14. The display panel according to claim 9, wherein the display panel comprises a base substrate, a polysilicon layer, a first metal layer, a capacitor metal layer, a second metal layer, a third metal layer, a transparent conductive layer, and an anode layer which are sequentially stacked on the base substrate.

15. The display panel according to claim 14, wherein the light-shielding pattern is disposed between the base substrate and the polysilicon layer or between the third metal layer and the anode layer.

16. The display panel according to claim 14, wherein a vertical projection of the reset connecting line on the light-emitting surface does not intersect a vertical projection of the power connecting line on the light-emitting surface and a vertical projection of the data connecting line on the light-emitting surface, respectively; the power connecting line, the data connecting line, and the reset connecting line are transparent wires, and the light emission control connecting line and the scan connecting line are non-transparent wires; and
the light emission control signal line and the light emission control connecting line are disposed in the first metal layer, the scan signal line and the scan connecting line are disposed in the second metal layer, the light-shielding pattern is disposed in the third metal layer, and the power signal line, the data signal line, the reset signal line, the power connecting line, the data connecting line, and the reset connecting line are disposed in the transparent conductive layer.

17. The display panel according to claim 1, wherein a vertical projection of the plurality of light-emitting elements on a light-emitting surface at least partially overlaps a vertical projection of the plurality of pixel driver circuits on the light-emitting surface, and the plurality of pixel driver circuits are located on one side of the plurality of light-emitting elements facing away from the light-emitting surface.

18. The display panel according to claim 3, wherein the plurality of pixel driver circuits constitute a plurality of island-shaped regions and form the plurality of light-transmitting regions located among the plurality of island-shaped regions, and the plurality of island-shaped regions are sequentially arranged in a row direction and a column direction; and
each of the plurality of island-shaped regions comprises at least two adjacent pixel driver circuits of the plurality of pixel driver circuits, and the plurality of island-shaped regions are connected to one another through the plurality of pixel drive signal lines.

19. The display panel according to claim 18, wherein a vertical projection of a gap between adjacent and non-transparent pixel drive signal lines among pixel drive signal lines connected to pixel driver circuits within a same one of the plurality of island-shaped regions on the light-emitting surface is located within the vertical projection of the light-shielding pattern on the light-emitting surface.

20. The display panel according to claim 18, wherein island-shaped regions of the plurality of island-shaped regions in two adjacent rows are staggered from one another.

21. The display panel according to claim 18, wherein the plurality of light-emitting elements comprise a red light-emitting element, a green light-emitting element, and a blue light-emitting element, the plurality of light-emitting elements constitute a plurality of pixels, and the plurality of pixels are disposed in one-to-one correspondence with the plurality of island-shaped regions; and
each of the plurality of pixels comprises one red light-emitting element, one green light-emitting element, and one blue light-emitting element which are adjacent to one another; or, each of the plurality of pixels comprises one red light-emitting element, two green light-emitting elements, and one blue light-emitting element which are adjacent to one another.

22. The display panel according to claim 18, wherein island-shaped regions of the plurality of island-shaped regions in any row are connected to island-shaped regions of the plurality of island-shaped regions in an adjacent row in one-to-one correspondence through the plurality of pixel drive signal lines; or, island-shaped regions of the plurality of island-shaped regions in any row are connected to island-shaped regions of the plurality of island-shaped regions in an interlaced row in one-to-one correspondence through the plurality of pixel drive signal lines.

23. The display panel according to claim 22, wherein the plurality of pixel drive signal lines are arc-shaped or broken-line shaped.

24. A display device, comprising a display panel;
wherein the display panel comprises a display region and a plurality of pixel driver circuits, the display region comprises a first display region and an optical component region, and the optical component region comprises a plurality of light-emitting elements and a plurality of light-transmitting regions; and
wherein the plurality of pixel driver circuits are electrically connected to the plurality of light-emitting elements; the plurality of pixel driver circuits are connected to one another through a plurality of pixel drive signal lines, and at least one of the plurality of pixel drive signal lines is a transparent wire.
